(19) United States
(12) Patent Application Publication
(10) Pub. No.: US 2026/0126498 A1
(43) Pub. Date: May 7, 2026

(54) Thermal Runaway Detection System

(71) Applicant: IC Technologies, LLC, Troy, MI (US)

(72) Inventors: Youssef Mansour, Troy, MI (US); John Gelmisi, Troy, MI (US)

(73) Assignee: IC Technologies, LLC, Troy, MI (US)

(21) Appl. No.: 19/377,808

(22) Filed: Nov. 3, 2025

Related U.S. Application Data
(60) Provisional application No. 63/716,073, filed on Nov. 4, 2024.
(60) Provisional application No. 63/852,512, filed on Jul. 28, 2025.

(51) Int. Cl. G01R 31/392; G01R 31/36; G01R 31/3828; H01M 10/63

(52) U.S. Cl. CPC G01R 31/392; G01R 31/3648; G01R 31/3828; H01M 10/63

(57) ABSTRACT

A system and method for early detection of thermal runaway and electrochemical degradation in battery cells and packs includes a sensor with at least two conductive electrodes separated by a sub-millimeter gap and biased by a controlled voltage. When thermal runaway byproducts enter the gap, current between the electrodes is altered to produce a measurable signal, conditioned by onboard or remote circuitry through amplification/filtering to generate a processed signal. This signal is transmitted to a battery control system to initiate protective actions (e.g., shutdown, cooling activation, or cell isolation). The sensor may be implemented on a printed circuit board or as discrete electrodes and may include a gas-permeable filter that admits vapors and fine aerosols while blocking liquids and debris. The disclosed system enables real-time, sub-second detection of early thermal runaway precursors before temperature rise or combustion occurs, enhancing safety and reliability of lithium-ion and other electrochemical energy storage systems.

This application claims benefit of and priority to U.S. Provisional Application Ser. No. 63/852,512 filed Jul. 28, 2025 entitled Method for Detection of Internal Electrochemical Degradation and Thermal Runaway of Lithium Ion Batteries and U.S. Provisional Application Ser. No. 63/716,073 filed Nov. 4, 2024 entitled Method for Detection of Internal Electrochemical Degradation and Thermal Runaway of Lithium Ion Batteries, both of which are hereby incorporated herein by reference in their entireties.

### BACKGROUND

Certain power sources, such as lithium-ion and lithium-metal battery cells, can undergo various types of failures. Such failures have been known to initiate a process commonly referred to “thermal runaway”. Thermal runaway may result in a rapid increase in battery cell temperature accompanied by the release of flammable byproducts, such as electrolytes, particulates, and/or chemical gases. These flammable byproducts may pose a significant ignition risk which can potentially lead to fires; endangering occupants and bystanders.

Flammable byproducts resulting from thermal runaway, such as flammable gases, will often be ignited by the battery's high temperature. Such an ignition may result in a fire which, in turn, may spread to other cells, thus causing the thermal runaway. In light of the widespread use of such battery cells in applications such as electric vehicles, portable electronics, and energy storage systems, early detection of thermal runaway is crucial for ensuring safety of such battery systems.

Traditional detection methods for thermal runaway typically rely on a combination of sensor technologies that may be integrated into a battery management system. These systems monitor factors such as temperature, voltage, gas emissions, and pressure changes to detect early signs of thermal runaway.

Temperature sensors may be used to detect local hotspots within the battery pack, but their effectiveness is limited by response times and the potential for undetected localized heating. Voltage sensors may detect overcharging or discharging by measuring terminal voltage changes. Thermistors, thermocouples, and digital temperature sensors may also be used despite limitations in detection accuracy and environmental sensitivity. Gas sensors, such as for detecting hydrogen, carbon monoxide, and carbon dioxide, may provide early warning signs of thermal runaway by detecting the release of volatile organic compounds and gasses during the initial stages of exothermic reactions.

However, these approaches have limitations in terms of early detection and reliability, as they often respond to later stages of the thermal runaway process. It would be beneficial to provide a system in which thermal runaway is detected at an earlier stage so as to provide rapid and precise alerts for mitigating potential hazards effectively.

### SUMMARY

Disclosed herein are systems, devices, and methods for efficiently and rapidly detecting thermal runaway events and hydrogen leakage, enabling early intervention and mitigation measures.

The systems, devices, and methods disclosed herein may utilize a sensor having a pair of electrodes separated by a predefined gap of sufficient width to prevent closing of a circuit between the electrodes absent presence of gasses and electrochemical species or the like which are indicative of thermal runaway conditions.

A sensor may be attached to a specific prismatic cell or to a module or pack of multiple cells. The sensor may be attached to a gas-venting location of a battery module or to a dedicated access opening in a lid of a prismatic cell. In either case, a gas-permeable filter or membrane may be positioned between the gas-venting location or dedicated access opening and the electrodes that admits vapors and/or fine aerosols while rejecting liquid electrolyte splash, condensate, and/or debris.

Upon the circuit between the electrodes being closed due to the presence of any such thermal runaway indicators, a raw voltage signal may be transmitted by the sensor to a conditioning circuit or onboard measurement and diagnostic module for filtering, amplification, and/or other processing. The processing of the raw signal may be performed for each such sensor, or a plurality of sensors may be transmitted to a common conditioning circuit. The processed signal may then be transmitted to a battery control system for further action (e.g., cutoff, alarms, etc.) so as to quickly react to the thermal runaway conditions.

In some aspects, the techniques described herein relate to a sensor system configured for thermal runaway mitigation through feedback control, enabling dynamic responses based on sensor data.

In some aspects, the techniques described herein relate to a sensor system incorporating sensitivity calibration capable of predicting early or late-stage thermal runaway events based on selected detection modes such as low voltage sensing, high voltage sensing, and calibratable thresholds.

The sensor may include specific filter designs for electrolyte and particulate protection, with filters varying in size, type, and material depending on the anticipated environment and specific application.

The sensor may be positioned either inside or outside a battery cell or enclosure, depending on application requirements and design constraints. Additionally, the sensor structure may be flexible or rigid to accommodate diverse battery configurations.

The sensor may include strategically sized holes of varying diameters to facilitate controlled vent gas ingress to the sensor, optimizing detection sensitivity.

The sensor can be constructed to function as a standalone unit or may be integrated directly within the battery enclosure, thereby providing flexibility in deployment scenarios. Furthermore, the sensor can be either physically separated from or integrated directly with its processing unit.

The sensing elements or electrodes can be implemented as conductive tracks printed on a rigid or flexible printed circuit board (PCB) or as separate probes. These sensing tracks may be flush-mounted or raised (e.g., up to a height of approximately 10 millimeters above the PCB surface) to enhance sensitivity and reliability.

The electrodes may be electrically charged by a direct current.

The electrodes may be electrically charged by an alternating current.

In some aspects, the techniques described herein relate to a system, wherein the sensor is operable to detect internal electrochemical changes in lithium ion batteries and battery deterioration as well as battery thermal runaway.

In some aspects, the techniques described herein relate to a thermal runaway detection system, including: a processing unit; a sensor in communication with the processing unit, the sensor including a first electrode, a second electrode, and a gap between the first electrode and the second electrode; wherein the first electrode and/or the second electrode are electrically charged with a voltage such that, upon one or more thermal runaway byproducts entering the gap, a change in current occurs between the sensor electrodes produces a signal indicative of a thermal runaway event.

In some aspects, the techniques described herein relate to a thermal runaway detection system, wherein the gap is between 0.05 millimeters and 2.0 millimeters, thereby providing sufficient sensitivity for conductive gas detection.

In some aspects, the techniques described herein relate to a thermal runaway detection system, wherein the voltage ranges from 500 volts to 1,000 volts depending on the selected detection mode.

In some aspects, the techniques described herein relate to a thermal runaway detection system, wherein a source of the voltage is selected from a group consisting of a direct current source, an alternative current source, and a microwave source, each configured to bias the electrodes and enable gas ionization or conductivity-based sensing.

In some aspects, the techniques described herein relate to a thermal runaway detection system, wherein the voltage ranges from 3 volts to 500 volts in a low-voltage sensing mode for conductivity change detection.

In some aspects, the techniques described herein relate to a thermal runaway detection system, wherein the one or more thermal runaway byproducts include lithium ions, particulates, electrons, hydrocarbons, and/or hydrogen gases that alter the electrical conductivity within the electrode gap.

In some aspects, the techniques described herein relate to a thermal runaway detection system, wherein the sensor is included of a rigid PCB, a flexible PCB, or separate electrodes each including conductive tracks defining the first and second electrodes and the gap.

In some aspects, the techniques described herein relate to a thermal runaway detection system, wherein the PCB sensor includes tracks up to 10 millimeters in height to increase exposed sensing area and gas interaction.

In some aspects, the techniques described herein relate to a thermal runaway detection system, wherein the sensor is attached to at least partially cover a vented opening of a battery cell such that gases vented from the cell directly enter the sensing region.

In some aspects, the techniques described herein relate to a thermal runaway detection system, wherein the sensor is integrated with the processing unit enabling local signal conditioning and reducing transmission noise.

In some aspects, the techniques described herein relate to a thermal runaway detection system, wherein the sensor is separate from the processing unit.

In some aspects, the techniques described herein relate to a thermal runaway detection system, wherein the sensor includes a gas-permeable filter positioned over the electrode gap.

In some aspects, the techniques described herein relate to a thermal runaway detection system, wherein the gas-permeable filter is configured to admit vapors and/or fine aerosols while rejecting liquid electrolyte splash, condensate, and/or debris.

In some aspects, the techniques described herein relate to a thermal runaway detection system, wherein the system includes a thermal runaway prevention feedback control mechanism configured to initiate protective measures upon receiving the signals from the sensor, the protective measures including at least one of system shutdown, activation of cooling systems, isolation of affected battery cells, cessation of battery charging, and cessation of battery discharging.

In some aspects, the techniques described herein relate to a method of detecting thermal runaway in a battery cell, including: mounting a sensor to an access opening of the battery cell such that the sensor is exposed to the internal headspace of the cell, the sensor including a first electrode, a second electrode, and a gap between the first electrode and the second electrode; producing a raw signal by closing a circuit between the first electrode and the second electrode due to a presence of a thermal runaway indicator; processing the raw signal by a conditioning circuit to produce a processed signal; and transmitting the processed signal to a battery control system.

In some aspects, the techniques described herein relate to a method, wherein the sensor is operable to detect internal electrochemical changes in lithium ion batteries and battery deterioration as well as battery thermal runaway enabling detection of gases prior to external venting.

In some aspects, the techniques described herein relate to a method, wherein the conditioning circuit is integrated with the sensor and performs local amplification, filtering, and signal stabilization before transmission to the control system.

In some aspects, the techniques described herein relate to a method, wherein the sensor includes a gas-permeable filter configured to allow passage of gasses while restricting passage of liquids.

In some aspects, the techniques described herein relate to a method, wherein the step of processing the raw signal includes amplifying, filtering the raw signal and applying a threshold algorithm to discriminate early venting or decomposition signals from normal operating variations.

In some aspects, the techniques described herein relate to a method of detecting thermal runaway in a module or battery pack, including: mounting a sensor at a gas-venting location of the module or within a pack enclosure, the sensor including a first electrode, a second electrode, and a gap between the first electrode and the second electrode, and the battery pack including a plurality of battery cells; producing a raw signal by closing a circuit between the first electrode and the second electrode due to a presence of a thermal runaway indicator; processing the raw signal by a conditioning circuit to produce a processed signal; and transmitting the processed signal to a battery control system configured to initiate safety responses including isolation of affected cells, activation of cooling, or system shutdown.

### BRIEF DESCRIPTION OF THE DRAWINGS

These and other aspects, features and advantages of which embodiments of the invention are capable of will be apparent and elucidated from the following description of embodiments of the present invention, reference being made to the accompanying drawings, in which

FIG. 1 is a block diagram of a processing unit of a thermal runaway detection system in accordance with an example.

FIG. 2 is a perspective view of a sensor of a thermal runaway detection system in accordance with an example.

FIG. 3 is a diagram of a sensor of a thermal runaway detection system in accordance with an example.

FIG. 4 is a graph illustrating sensor signal, battery temperature, and battery voltage changes during initiation of thermal runaway in accordance with an example.

FIG. 5 is a block diagram and flowchart of a thermal runaway detection system in accordance with an example.

FIG. 6 is a perspective view of a sensor mounted at a gas-venting location of a battery module of a thermal runaway detection system in accordance with an example.

FIG. 7 is a perspective view of a sensor of a thermal runaway detection system in accordance with an example.

FIG. 8 is a perspective view of a prismatic cell and sensor of a thermal runaway detection system in accordance with an example.

FIG. 9 is a pair of perspective views of a sensor of a thermal runaway detection system in accordance with an example.

FIG. 10 is a block diagram illustrating a sensor of a thermal runaway detection system in accordance with an example.

### DETAILED DESCRIPTION

Specific embodiments of the invention will now be described with reference to the accompanying drawings. This invention may, however, be embodied in many different forms and should not be construed as limited to the embodiments set forth herein; rather, these embodiments are provided so that this disclosure will be thorough and complete, and will fully convey the scope of the invention to those skilled in the art. The terminology used in the detailed description of the embodiments illustrated in the accompanying drawings is not intended to be limiting of the invention. In the drawings, like numbers refer to like elements.

For the purposes of this specification, use of the terms “about”, “around”, or “approximately” when referring to a value may be understood to mean within 10% of the stated value (either greater or lesser), inclusive.

Disclosed herein are systems, methods, and devices for detecting adverse conditions such as thermal runaway and/or hydrogen leakage. The systems, methods, and devices disclosed herein may be utilized to detect such conditions in a wide range of areas, including but not limited to in a vehicle. Preferably, upon detection of an adverse condition such as thermal runaway or hydrogen leakage, a signal will be generated for further processing, such as for activating an alarm system to immediately warn any person in the vicinity of the adverse conditions.

Electric vehicles, which are becoming more ubiquitous in modern times, commonly rely on battery cells, such as lithium-ion and lithium-metal battery cells. Tests were conducted to analyze various gases that are vented from such battery cells undergoing thermal runaway at different states of charge to evaluate the risk of the buildup and ignition of battery gases.

Examples of gases identified as being released before and/or during thermal runaway include but are not limited to hydrocarbon species such as methane, ethylene, and propylene. Nitrogen, hydrogen, carbon monoxide, and carbon dioxide may also be released during the thermal runaway process. Finally, lithium ion particulates and free electrons may also be released during thermal runaway.

Lithium-ion and lithium-metal battery cells may contain an organic compound electrolyte that decomposes when a battery cell undergoes thermal runaway. The electrolyte may comprise a lithium salt dissolved in an organic solvent. Examples of organic solvents commonly found in such battery cells include ethylene carbonate, diethyl carbonate, dimethyl carbonate, propylene carbonate, dimethoxyethane, gamma-butyrolactone, and the like. The diversity of organic solvents found in such battery cells may cause a variety in the concentrations of exhaust gas constituents. However, the majority of the exhaust gas constituents will be typically made up of carbon, hydrogen, and oxygen as well as particulates such as lithium, lithium ions, and free electrons.

As the temperature increases within a battery cell, the organic compound begins to react with other components of the battery cell. Such reactions may lead to an increase in battery cell temperature and the production of flammable lithium ions, particulates, electrons, hydrocarbon, and hydrogen gases. These byproducts of such reactions may be used as a precursor to create a signal.

Disclosed herein are various systems, methods, and devices for very rapidly detecting conditions resulting from initiation of thermal runaway conditions in a power source such as a battery. The systems, methods, and devices shown and/or described herein may detect free electrons released before thermal runaway, lithium ions prior to the onset of deterioration due to thermal propagation, gasses, and/or organic electrolytes that may decompose during thermal runaway.

The systems, methods, and devices disclosed herein have demonstrated capability to meet or exceed regulatory requirements and enhance safety protocols in battery-powered systems. By monitoring the ion gas concentration, the systems, methods, and devices disclosed herein may provide an early warning system that enables preventative measures to be taken prior to the onset of a catastrophic event. The safety and reliability of energy storage systems may thus be significantly enhanced, thereby contributing to the broader goal of ensuring safe and widespread adoption of advanced battery technologies.

In the initial stage of thermal runaway, elevated temperatures within the battery may cause structural disruptions in the cathode material, leading to metal ion dissolution into the electrolyte. This process typically generates specific vapor emissions detectable by the sensor.

Subsequently, further thermal increases may prompt decomposition of the Solid Electrolyte Interphase (SEI) film, a protective layer formed on electrode surfaces during normal battery operation. SEI film decomposition significantly contributes to additional heat generation and vapor release.

Finally, continued heating facilitates reactive interactions between lithium ions and electrolyte solvents. This interaction may produce distinctive chemical vapor signatures and may initiate a self-sustaining chain reaction of escalating electrolyte and battery material degradation, critical for timely detection and mitigation through sensor technologies.

Once these vapors pass by the sensor electrodes, the circuit between positive and negative electrodes may close, thereby producing a signal indicative of the thermal runaway detection before flames develop.

Examples of sensors for detection of such conditions based on either of the aforementioned methods may comprise a simple pair of electrically isolated electrodes, a multi-pole sensor with one or more negative terminals and one or more positive terminals, and the like.

It should also be appreciated that the methods, systems, and devices shown and/or described herein may also be utilized for detection of hydrogen leakage. Certain applications that utilize hydrogen as a fuel include but are not limited to propulsion systems, power generation systems, and the like. Such systems may experience hydrogen leakage which can be considered a safety hazard due to the flammable nature of hydrogen. The various example sensor embodiments shown and/or described herein may be utilized to detect hydrogen leakage in the same manner as described in connection with thermal runaway in batteries. Applications may include hydrogen engines, fuel cells, hydrogen supply lines, and the like.

Specific embodiments are described below. However, it should be appreciated that any of the features from any of the embodiments can be mixed and matched with each other in any combination. Hence, the present invention should not be restricted to only these embodiments, but any broader combination(s) thereof.

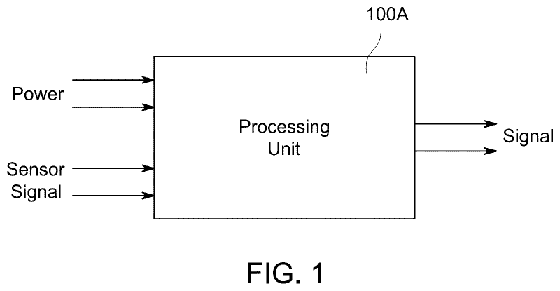

FIG. 1 illustrates a processing unit 100A according to an example. As shown, the processing unit 100A may receive power, such as from a power supply. The processing unit 100A may also receive a sensor signal, such as from a sensor 110 as described herein. Various types of processing units 100A may be utilized, including but not limited to CPU's, microcontrollers, systems-on-a-chip, integrated circuits, analog circuits, and the like. Generally, the processing unit 100A may be configured to output a signal indicating development of a potentially hazardous situation, such as thermal runaway or hydrogen leakage, upon receiving a signal from a sensor 110.

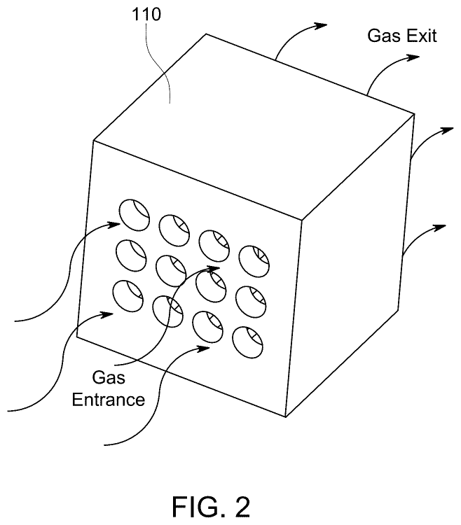

FIG. 2 illustrates an example of a sensor 110 including passages through which gas may pass between an inlet and an outlet. It should be appreciated that the example illustrated in FIG. 2 is merely for illustrative purposes only, and various sensors 110 having different constructions than shown may be utilized in different embodiments.

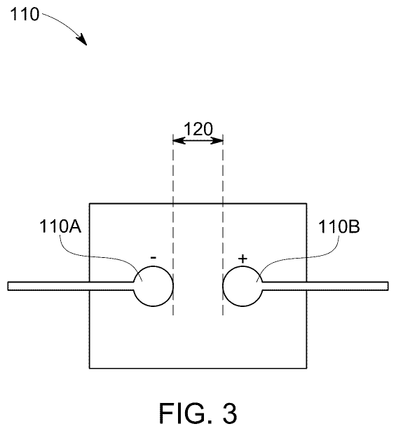

FIG. 3 illustrates an example of a sensor 110 including a first electrode 110A, a second electrode 110B, and a gap 120 between the first and second electrodes 110A, 110B. In the illustrated example, the first electrode 110A may comprise a negative terminal and the second electrode 110B may comprise a positive terminal. However, the reverse configuration may be utilized in different embodiments.

Generally, the gap 120 between the first and second electrodes 110A, 110B will be sufficient to prevent closing of a circuit between the electrodes 110A, 110B absent presence of gases and electrochemical species (e.g., lithium ions, particulates, electrons, nitrogen, hydrogen, carbon monoxide, carbon dioxide, and hydrocarbon species such as methane, ethylene, propylene, ethylene carbonate, diethyl carbonate, dimethyl carbonate, propylene carbonate, dimethoxyethane, and gamma-butyrolactone) or the like which are indicative of thermal runaway. By way of example and without limitation, the gap 120 may comprise between about 0.05 mm and 2.0 mm. However, in some embodiments, a gap of less than 0.05 mm may be utilized. In further example embodiments, a gap greater than 2.0 mm may be utilized.

In an example, the electrodes 110A, 110B may be electrically charged with either DC voltage, AC voltage, or a microwave source. In an example embodiment which relies on high voltage, voltage ranging from 500 volts to 1,000 volts may be utilized. Generally, upon entry of gasses (e.g., hydrogen, nitrogen, hydrocarbon, etc.) and/or particulates (e.g., lithium ion), such gasses and/or particulates will be detected under the high voltage so as to close a circuit in the sensor 110 and produce a signal. The resulting signal may then be communicated to the processing unit 100A, which may be in communication with the sensor 110, for further processing as discussed in more detail below.

In another example which relies on lower voltage, voltage ranging from 3 volts to 500 volts may be utilized. During early thermal runaway stages, heating disrupts the cathode structure causing metal ion dissolution into the electrolyte, followed by the decomposition of the SEI film and subsequent reactions between lithium ions and electrolyte solvents. These processes release distinctive vapors which may be relied upon to close the circuit between the electrodes 110A, 110B. Upon entry into the gap 120, a resulting signal, which may be in the order of millivolts, may be amplified such that the sensor 110 may detect any gasses and/or particulates indicative of thermal runaway before flames are produced.

The examples shown and/or described herein may detect thermal runaway in a single cell before fire catches any remaining cells and/or modules. Thus, the examples shown and/or described herein may provide an accurate detection apparatus for detecting thermal runaway conditions before they spread to other cells/modules or cause flames to be produced.

It is noted that, although the example of FIG. 3 illustrates only a single positive electrode 110B and a single negative electrode 110A, more electrodes 110A, 110B may be utilized in different embodiments. For example, multiple negative electrodes 110A may be grouped together and/or multiple positive electrodes 110B may be grouped together, with the respective groups of electrodes 110A, 110B being separated by a gap 120. The use of multiple electrodes may increase surface area for better or more accurate detection.

During testing, fully charged batteries were equipped with sensors 110 at any location where gases may form and pass by the sensors 110. The gasses passing by the sensors 110 cause a signal detection between the electrically charged electrodes 110A, 110B, which alerts the system that gases have been detected and thus thermal runaway is possible.

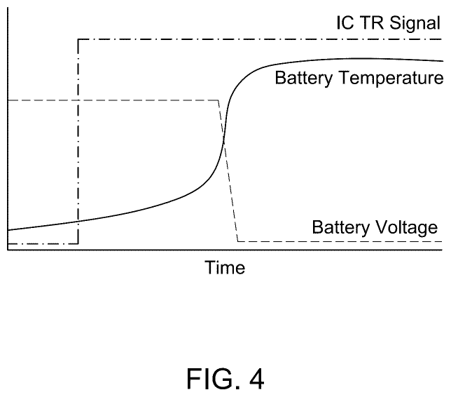

FIG. 4 is a graph illustrating battery voltage, battery surface temperature, and sensor signal detecting venting of gases. As the battery starts to undergo thermal runaway, the battery voltage begins to gradually drop. At the same moment, the battery cell starts generating gases that are immediately detected by the sensor 110. Detection can take place even before the voltage starts dropping. The thermal runaway is an exothermic process that produces energy, heating the cell which is indicated by the rise in battery surface temperature.

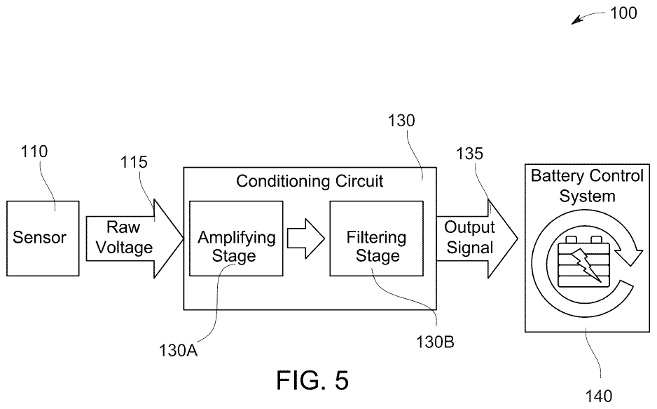

FIG. 5 is a block diagram and flowchart of a thermal runaway detection system 100 in accordance with an example. FIG. 5 illustrates the sensor signal path from electrochemical sensing to output delivery, including a sensor 110 outputting raw voltage 115 and a conditioning circuit 130 including an amplification stage 130A and a filtering stage 130B which may produce an output signal 135 to be transmitted to a battery control system 140.

The sensor 110 may produce a raw signal that may be conditioned by, e.g., biasing, amplification, and filtering within a conditioning circuit. The sensor 110 may generate a signal proportional to changes in gas composition and/or concentration within the gas environment.

The raw signal may then be processed and transmitted as an output signal to a cell-sensing controller or battery management system. The raw signal may be processed by a conditioning circuit 130. The conditioning circuit 130 may include an amplification stage 130A and a filtering stage 130B. The conditioning circuit 130 may generally provide amplification, filtering, and signal processing (e.g., weighted averaging, rate-of-change, hysteresis) to yield a robust event metric.

The amplification stage 130A may apply biasing and perform preamplification to establish a stable operating point and amplify small input currents into a usage voltage signal. Additionally, programmable gain may be employed to span early warning thresholds, enabling dynamic sensitivity adjustment based on signal conditions.

The filtering stage 130B may implement one or more passive or active filtering circuits configured to reject electromagnetic interference (EMI) across a defined frequency spectrum. These filtering circuits may employ various types of filters, such as low-pass filters, high-pass filters, and band-pass filters tailored to suppress common-mode and differential-mode sources of EMI. By attenuating unwanted high-frequency signals prior to amplification or digitization, the filtering stage 130B may enhance signal integrity and reduce susceptibility to external noise.

The filtering stage 130B may include a notch filter configured to attenuate specific frequency components associated with persistent or narrowband interference sources. The notch filter may be tuned to reject known EMI frequencies. By selectively suppressing targeted frequencies while preserving adjacent signal content, the notch filter may enhance overall signal clarity and reduce false triggering in downstream processing stages.

The filtering stage 130B may include an anti-aliasing filter configured to attenuate high-frequency components that exceed the Nyquist frequency of a sampling stage. By suppressing spectral content that could fold into lower frequencies during digitization, the anti-aliasing filter may preserve signal fidelity and prevent aliasing artifacts in the digital domain.

The raw voltage signal from the sensor 110 may thus pass through the conditioning circuit 130, including an amplifying stage 130A and a filtering stage 130B, to produce an output signal that may be transmitted to a battery control system 140. This output signal may be utilized to detect early onset of a thermal runaway event as discussed herein so that the battery control system can take appropriate mitigating actions (e.g., shutting down, draining, and/or ejecting any relevant modules, initiation of an alarm, separation of any affected batteries or modules, and/or opening of a fuse to prevent the thermal runaway from affecting any remaining cells, among other steps as discussed in more detail below.

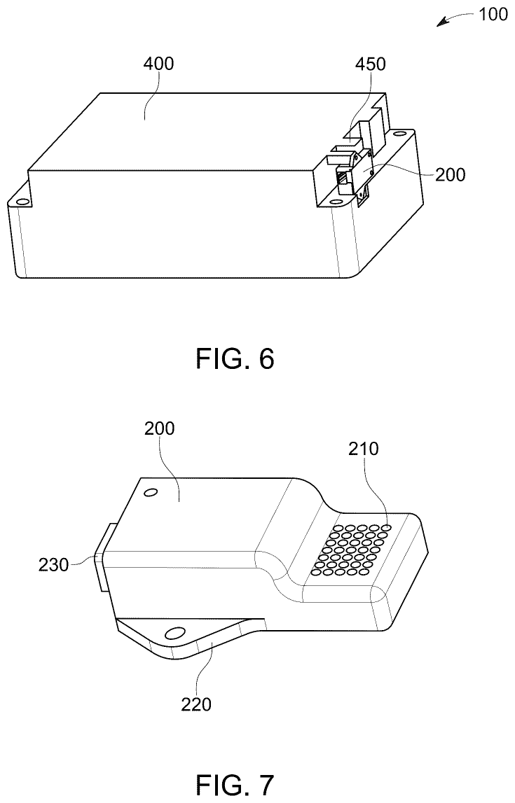

FIGS. 6-7 illustrate an example of an external, all-inclusive thermal runaway detection system 100 which may be utilized for monitoring of a module/pack vent.

FIG. 6 is a perspective view of a sensor 200 mounted at a gas-venting location 450 of a battery module 400 of a thermal runaway detection system 100 in accordance with an example. As shown, a self-contained sensor 200 may be mounted on a battery module 400 or inside a battery pack. The sensor 200 may be comprised of the sensor 110 shown in FIG. 3 including a pair of electrodes 110A, 110B separated by a gap 120. In the illustrated example of FIG. 6, it can be seen that the sensor 200 may be placed outside the cell cans and along a venting path of the module 400 or pack.

FIG. 7 is a perspective view of a sensor 200 of a thermal runaway detection system 100 in accordance with an example. The sensor 200 may include both a sensing element and full conditioning electronics. Vent openings in the sensor housing may admit gasses and particulates from the module/pack headspace to contact the sensing surface of the sensing element. A sealed connector may provide both power and a processed output signal to a downstream controller.

The sensor 200 may be fastened to a housing of a battery module 400 at a designated built-in vent opening 450. A vented face of the sensor 200 may be aligned with the internal gas-relief path of the battery module 400 such that any exhaust from one or more battery cells of the battery module 400 may reach the sensing surface of the sensor 200 quickly.

The sensor 200 may include a vented face 210 including an array of openings that allow gas ingress. The positioning, orientation, shape, configuration, and number of such openings may vary in different examples and thus should not be construed as limited in scope by the illustrated example of FIG. 6.

A protective barrier at the inlet of the sensor 200 may admit gasses and fine aerosols while rejecting liquid splash and debris. A sensing element and conditioning circuit as previously described may be integrated within the sensor 200 to provide biasing, amplification, filtering, and a stable output signal to a connector 230 which may be communicatively connected to a battery control system 140 or other type of monitoring or control unit.

The connector 230 may also supply power to the sensor 200. Harness routing from the connector 230 may lead to the module's monitoring or control unit, which may log the signal, trigger alarms, or initiate protective actions.

The shape, size, configuration, positioning, and orientation of the sensor 200 with respect to the battery module 400 may vary in different examples. The sensor 200 may be oriented vertically or horizontally to suit different types of battery modules 400 and packaging. A thin shroud or manifold may be utilized to effectively couple the vent flow directly into the inlet of the sensor 200 which may further improve response time.

The sensor 200 may be attached to various types of mounting features on the module 400 itself. The manner by which the sensor 200 may be attached to the module 400 may thus vary in different examples. Seals or gaskets may be utilized to maintain sensor 200 integrity under vibration and thermal cycling.

The sensor 200 may include connecting features 220 such as flanges, brackets, projections, indentations, and the like which may be configured to couple with corresponding mounting features of the module 400. In an example, the sensor 200 may include one or more flanges and mounting holes to enable rigid attachment to rails or pack panels; with the vent face 210 being oriented toward engineered gas-relief paths so that exhaust from any cell reaching the sensing element quickly.

In contrast to in-cell examples that access the headspace directly inside each cell for the earliest possible indication such as described below, the examples illustrated in FIGS. 6-7 may detect the same phenomena once gasses have exited the cell and entered the module 400 or pack headspace. Such examples may thus be well-suited for battery packs or racks of batteries with minimal wiring and without adding penetrations to individual cans while still providing rapid, early warning as soon as venting commences.

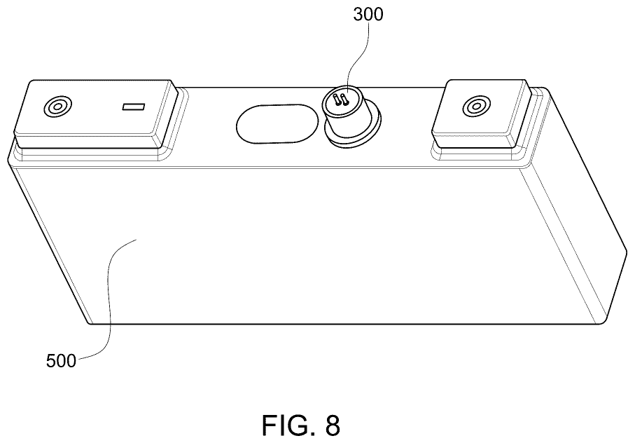

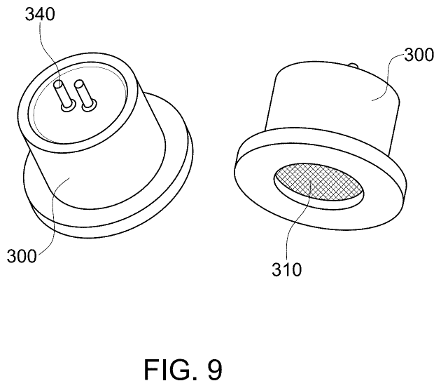

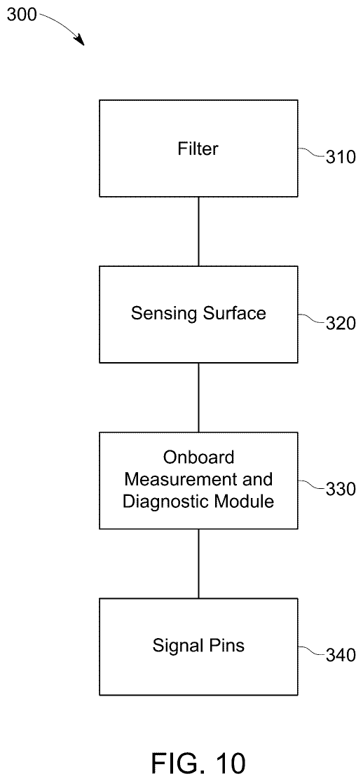

FIGS. 8-10 illustrate a thermal runaway detection system 100 in use with a prismatic cell 500. FIG. 8 is a perspective view of a prismatic cell 500 and sensor 300 of a thermal runaway detection system 100 in accordance with an example. FIG. 9 is a pair of perspective views of a sensor 300 of a thermal runaway detection system 100 in accordance with an example. FIG. 10 is a block diagram illustrating a sensor 300 of a thermal runaway detection system 100 in accordance with an example.

As shown in FIG. 8, a sensor 300 may be mounted directly to a prismatic cell 500 through use of a dedicated access opening in a lid of the prismatic cell 500. The sensor 300 may be comprised of the sensor 110 shown in FIG. 3 including a pair of electrodes 110A, 110B separated by a gap 120.

The manner by which the sensor 300 may be so mounted to the prismatic cell 500 may vary in different examples, and may include such features as a gasket, crush washer, weld collar, or the like to secure the sensor 300 over the opening while maintaining access to gasses and preventing liquid leakage. An inlet of the sensor 300 may face the headspace of the cell 500 so as to allow internal gasses and vapors to diffuse into the sensing cavity with a short path length for faster response time.

In typical use scenarios, a plurality of prismatic cells 500 may be stacked within a module; with each prismatic cell 500 being fitted with an identical, top-mounted sensor 300. The module itself may include a conditioning unit as previously described to handle amplification, filtering, and processing of a raw signal prior to communicating a processed signal to a battery-management system.

Various wiring/connection configurations may be utilized. In a first example utilizing per-cell channels, each sensor 300 may run to its own input on the conditioning unit, thus enabling cell-specific detection, trending, and fault isolation. In a second example, a ganged line may be utilized in which all sensors of a module may share a common line into the conditioning unit to provide earliest event detection with reduced wiring and electronics complexity. Thus, in a first example, each sensor 300 of a module may include its own dedicated conditioning circuit. In a second example, a plurality of sensors 300 may collectively feed into a common conditioning circuit.

Turning to FIGS. 9-10, a sensor 300 may comprise a filtration element (e.g., filter) 310 at its inlet, a protected sensing surface 320 positioned behind the filter 310, and an onboard measurement and diagnostic module 330; all contained within a common housing. The shape, configuration, and size of the housing may vary. In some examples, the housing may comprise a cylindrical structure with a flange surrounding its outer circumference at its lower end. Signal pins 340 or another type of connector may provide electrical connection to a downstream conditioning circuit on a cell-sensing controller or battery management system.

The sensing surface 320 may be packaged in a compact housing with a seal that allows installation at an access point, such as an opening, on a battery cell 500 within a fixture. The inlet side of the sensor 300 may include a gas-permeable filter 310 that admits vapors and fine aerosols from the headspace of the cell 500 while rejecting liquid electrolyte splash, condensate, and debris. The filter 310 may be composed of various materials known to allow passage of gasses while restricting passage of liquids including, e.g., sintered metal, ceramic, PTFE, multilayer constructs (e.g., hydrophobic and particulate layers), selected for permeability, chemical compatibility, and splash resistance.

After the filter, the sensing surface 320 may comprise electrodes maintained at a defined gap and bias potential to transduce changes in gas composition or ions into an electrical parameter as previously discussed. The electrode gap and bias potential may be selected to yield high sensitivity to relevant vapors and/or ions.

As previously discussed and shown in FIG. 3, the sensing surface 320 may include a pair of electrodes 110A, 110B separated by a predefined gap 120. The pair of electrodes 110A, 110B may be maintained at the predefined gap 120 so as to bias potential transduce changes in gas composition or ions into an electrical signal for further conditioning and/or processing.

An onboard measurement and diagnostic module 330 may stabilize and condition this electrical signal, check connectivity, and confirm that the sensor 300 is operating within its calibrated range. More specifically, the onboard measurement and diagnostic module 330 may continuously check continuity to the harness, detect open/short faults, and verify operation within a calibrated range such that out-of-range or fault conditions may be flagged by a conditioning circuit (either dedicated to a single sensor 300 or common to a plurality of sensors 300). The onboard measurement and diagnostic module 330 may include programmable gain and temperature monitoring. In some examples, a temperature sensor may also be included for additional sensing functionality.

The rear of the housing of the sensor 300 may comprise a connector, such as signal pins 340, that may receive power and transmit measurement output. The housing and filter 310 materials may be selected for chemical compatibility and durability; with sealing achieved by a sealing element such as a gasket, crush washer, or welded collar. In operation, such an assembly may provide continuous, early detection of electrolyte vapors and related decomposition products associated with battery degradation and thermal runaway events.

By locating the sensor directly on the battery cell 500 as shown in FIG. 8 with a short diffusion path to the internal headspace, the system 100 may provide continuous monitoring of early chemical changes (e.g., electrolyte vapor onset, solid electrolyte interphase (SEI) related volatiles, other decomposition products, and the like) that may precede and thus provide warning of thermal runaway initiation. The filter 310 and cavity design may accelerate gas exchange while maintaining liquid rejection; thereby enabling fast response and robust operation over the lifetime of the battery cell 500. In the example illustrated in FIG. 9, the two-pin outlet of the signal pins 340 may simplify wiring and improve reliability in dense module environments, while the integrated diagnostics may allow detection of any circuit anomalies.

It would be beneficial for applications that use large capacity batteries and battery packs such as plug-in hybrids and fully electric vehicles to be equipped with a high accuracy, fast response thermal runaway detection device such as described herein. It would also be beneficial for more applications in the aviation industry including electric aircrafts, eVTOL, and the like. The various examples of sensors 110 shown and/or described herein have the capability to detect with high accuracy and real-time response the gas venting due to thermal runaway. This can allow the battery management system to apply early mitigation and/or prevention of catastrophic thermal failure events. In addition, the real-time detection capability can provide an early warning to allow occupants ample time for a safe evacuation. The examples disclosed herein would allow a proper design of the battery packs to allow the battery manufacturer to pass the safety requirements for releasing the battery packs to the market while meeting safety requirements.

It should be appreciated that the application of the sensor 110 should not be construed as limited exclusively to battery electric vehicles. The systems, devices, and/or methods shown and/or described herein may be applied to any battery module or packs of any size, whether in a mobile or stationary application.

Upon receipt of a signal from the sensor 110 indicative of thermal runaway, the processing unit 100A may perform a wide range of functionalities. By way of example, the processing unit 100A may direct any relevant modules to shut down and drain. By way of further example, the processing unit 100A may direct that any potentially affected modules be ejected. By way of yet another example, the processing unit 100A may direct initiation of an alarm (e.g., visual, haptic, audible, sensory, etc.) to alert any occupants or nearly individuals to vacate the area (e.g., exit a vehicle immediately). By way of yet another example, the processing unit 100A may be in communication with a battery management system which may separate any affected battery or batteries, or initiate various other safety measures. By way of another example, the processing unit 100A may initiate the opening of a fuse or fuses to prevent the thermal runaway from affecting any remaining cells.

In further examples, the system may include a thermal runaway prevention feedback control mechanism that utilizes signals received from the sensor to activate measures aimed at preventing thermal runaway events through early detection. These measures may include system shutdown, activation of cooling systems, isolating affected battery cells, and immediately stopping both charging and discharging processes.

Sensitivity calibration of the sensor allows for prediction and early detection capabilities tailored to various parameters. By calibrating against battery-specific characteristics such as chemistry, voltage levels, electrolyte composition, and ambient conditions, the system can accurately forecast imminent thermal runaway events, enhancing safety and operational reliability.

In further embodiments to ensure sensor reliability and longevity, protective filters can be employed within sensor 110. These filters are specifically designed for electrolyte and particulate protection, selecting appropriate sizes, materials, and types (e.g., porous membranes, ceramic, polymeric layers, etc.) according to environmental conditions and anticipated contamination risks.

Sensor placement versatility is a critical aspect of the disclosed system. Sensors may be deployed either internally within battery cells or externally.

Enclosures used to house sensors include deliberate and strategically sized perforations or holes of different diameters. This design facilitates the efficient and selective entry of vent gases, ensuring effective detection without unnecessary delay or contamination.

Sensors in accordance with the techniques described herein may operate independently as standalone units or may be embedded within battery enclosures, depending on design requirements and constraints. Integration flexibility also extends to the sensor's relationship with processing units, with configurations available for both separate and integrated sensor-processor assemblies.

The sensing elements may be implemented through innovative manufacturing techniques such as printed electronics on PCB boards or through the use of discrete sensor probes. Depending on the specific application and sensitivity requirements, these sensing tracks can be flush with the PCB surface or raised (e.g., up to approximately 10 millimeters), thereby offering enhanced detection capabilities and adaptability to varying operational environments.

The sensor can detect internal electrochemical changes in lithium ion batteries and battery deterioration as well as battery thermal runaway. Although the invention has been described in terms of particular embodiments and applications, one of ordinary skill in the art, in light of this teaching, can generate additional embodiments and modifications without departing from the spirit of or exceeding the scope of the claimed invention. Accordingly, it is to be understood that the drawings and descriptions herein are proffered by way of example to facilitate comprehension of the invention and should not be construed to limit the scope thereof.

What is claimed is:

1. A thermal runaway detection system, comprising: a processing unit; a sensor in communication with the processing unit, the sensor comprising a first electrode, a second electrode, and a gap between the first electrode and the second electrode; wherein the first electrode and/or the second electrode are electrically charged with a voltage such that, upon one or more thermal runaway byproducts entering the gap, a change in current between the sensor electrodes produces a signal indicative of a thermal runaway event.

2. The thermal runaway detection system of claim 1, wherein the gap is between 0.05 millimeters and 2.0 millimeters, thereby providing sufficient sensitivity for detection of a conductive gas.

3. The thermal runaway detection system of claim 1, wherein the voltage ranges from 500 volts to 1,000 volts depending on a selected detection mode.

4. The thermal runaway detection system of claim 1, wherein a source of the voltage is selected from a group consisting of a direct current source, an alternative current source, and a microwave source, each configured to bias the first electrode and second electrode so as to enable gas ionization or conductivity-based sensing.

5. The thermal runaway detection system of claim 1, wherein, in a low-voltage sensing configuration for detection of conductivity change, the voltage ranges from 3 volts to 500 volts.

6. The thermal runaway detection system of claim 1, wherein the one or more thermal runaway byproducts comprise lithium ions, particulates, electrons, hydrocarbons, and/or hydrogen gases that alter electrical conductivity within the gap between the first electrode and the second electrode.

7. The thermal runaway detection system of claim 1, wherein the sensor is comprised of a rigid PCB, a flexible PCB, or separate electrodes each including conductive tracks defining the first electrode, the second electrode, and the gap.

8. The thermal runaway detection system of claim 7, wherein the PCB sensor comprises tracks up to 10 millimeters in height to increase exposed sensing area and gas interaction.

9. The thermal runaway detection system of claim 1, wherein the sensor is attached to at least partially cover a vented opening of a battery cell such that gases vented from the cell directly enter a sensing region of the sensor.

10. The thermal runaway detection system of claim 1, wherein the sensor is integrated with the processing unit so as to enable local signal conditioning and reduce transmission noise.

11. The thermal runaway detection system of claim 1, wherein the sensor is separate from the processing unit.

12. The thermal runaway detection system of claim 1, wherein the sensor comprises a gas-permeable filter positioned over the gap between the first electrode and the second electrode.

13. The thermal runaway detection system of claim 12, wherein the gas-permeable filter is configured to admit vapors and/or fine aerosols while rejecting liquid electrolyte splash, condensate, and/or debris.

14. The thermal runaway detection system of claim 1, wherein the system comprises a thermal runaway prevention feedback control mechanism configured to initiate protective measures upon receiving the signals from the sensor, the protective measures comprising at least one of system shutdown, activation of cooling systems, isolation of affected battery cells, cessation of battery charging, and cessation of battery discharging.

15. A method of detecting thermal runaway in a battery cell, comprising:
mounting a sensor to an access opening of the battery cell such that a sensor is exposed to an internal headspace of the cell, the sensor comprising a first electrode, a second electrode, and a gap between the first electrode and the second electrode;
producing a raw signal by closing a circuit between the first electrode and the second electrode due to a presence of a thermal runaway indicator;
processing the raw signal by a conditioning circuit to produce a processed signal; and
transmitting the processed signal to a battery control system.

16. The method of claim 15, wherein the sensor is operable to detect internal electrochemical changes in lithium ion batteries and battery deterioration as well as battery thermal runaway so as to enable detection of gases prior to external venting.

17. The method of claim 15, wherein the conditioning circuit is integrated with the sensor and wherein the conditioning circuit performs local amplification, filtering, and signal stabilization prior to transmission to the battery control system.

18. The method of claim 15, wherein the sensor comprises a gas-permeable filter configured to allow passage of gasses while restricting passage of liquids.

19. The method of claim 15, wherein the step of processing the raw signal comprises amplifying, filtering the raw signal, and applying a threshold algorithm to discriminate early venting or decomposition signals from normal operating variations.

20. A method of detecting thermal runaway in a module or battery pack, comprising:
mounting a sensor at a gas-venting location of the module or within a pack enclosure, the sensor comprising a first electrode, a second electrode, and a gap between the first electrode and the second electrode, and the battery pack comprising a plurality of battery cells;
producing a raw signal by closing a circuit between the first electrode and the second electrode due to a presence of a thermal runaway indicator;
processing the raw signal by a conditioning circuit to produce a processed signal; and
transmitting the processed signal to a battery control system configured to initiate safety responses including isolation of affected cells, activation of cooling, or system shutdown.
